(19) United States
(12) Patent Application Publication
(10) Pub. No.: US 2024/0201584 A1
(43) Pub. Date: Jun. 20, 2024

(54) Photopolymers for Holographic Recording

(71) Applicant: DigiLens Inc., Sunnyvale, CA (US)

(72) Inventors: Shibu Abraham, Sunnyvale, CA (US); Milan Momcilo Popovich, Leicester (GB); Alastair John Grant, San Jose, CA (US); Ratson Morad, Palo Alto, CA (US); Hua Gu, Sunnyvale, CA (US); Gerald Buxton, Sunnyvale, CA (US)

(73) Assignee: DigiLens Inc., Sunnyvale, CA (US)

(21) Appl. No.: 18/553,512

(22) PCT Filed: Mar. 30, 2022
(86) PCT No.: PCT/US22/71444

§ 371 Date: Sep. 29, 2023

Related U.S. Application Data
(60) Provisional application No. 63/167,999, filed on Mar. 30, 2021.

(51) Int. Cl. G03F 7/00; C08F 2/50; G02B 5/32; G03F 7/031; G03F 7/105

(52) U.S. Cl. CPC G03F 7/001; C08F 2/50; G03F 7/031; G03F 7/105; G02B 5/32

(57) ABSTRACT

Waveguide based displays benefit from gratings which are capable of diffracting both S and P polarized light with high efficiency. While typical surface relief gratings (SRGs) diffract P polarized light efficiently, SRGs do not typically diffract S polarized light efficiently. One class of gratings that diffracts S polarized light with high efficiency is deep SRGs. One approach to producing deep SRGs is holographic polymer dispersed liquid crystal (HPDLC) gratings. In producing HPDLC gratings, a reactive monomer mixture is exposed to light in a polymerization process. Reactive monomer mixtures may include co-initiators and photo-initiator dyes. Co-initiators which include liquid amine synergist have been demonstrated to have advantageous results. Further, photo-initiator dyes with high extinction coefficients have demonstrated advantageous results.

### CROSS-REFERENCED APPLICATIONS

This application claims priority to U.S. Provisional Application 63/167,999 filed on Mar. 30, 2021, the disclosure of which is included herein by reference in its entirety.

### FIELD OF THE DISCLOSURE

The present invention generally relates to waveguides and methods for fabricating waveguides and more specifically to waveguide displays containing gratings for diffracting light from image sources and methods for fabricating said gratings.

### BACKGROUND

Waveguides can be referred to as structures with the capability of confining and guiding waves (i.e., restricting the spatial region in which waves can propagate). One subclass includes optical waveguides, which are structures that can guide electromagnetic waves, typically those in the visible spectrum. Waveguide structures can be designed to control the propagation path of waves using a number of different mechanisms. For example, planar waveguides can be designed to utilize diffraction gratings to diffract and couple incident light into the waveguide structure such that the in-coupled light can proceed to travel within the planar structure via total internal reflection (TIR).

Fabrication of waveguides can include the use of material systems that allow for the recording of holographic optical elements within or on the surface of the waveguides. One class of such material includes polymer dispersed liquid crystal (PDLC) mixtures, which are mixtures containing photopolymerizable monomers and liquid crystals. A further subclass of such mixtures includes holographic polymer dispersed liquid crystal (HPDLC) mixtures. Holographic optical elements, such as volume phase gratings, can be recorded in such a liquid mixture by illuminating the material with two mutually coherent laser beams. During the recording process, the monomers polymerize, and the mixture undergoes a photopolymerization-induced phase separation, creating regions densely populated by liquid crystal (LC) micro-droplets, interspersed with regions of clear polymer. The alternating liquid crystal-rich and liquid crystal-depleted regions form the fringe planes of the grating.

Waveguide optics, such as those described above, can be considered for a range of display and sensor applications. In many applications, waveguides containing one or more grating layers encoding multiple optical functions can be realized using various waveguide architectures and material systems, enabling new innovations in near-eye displays for Augmented Reality (AR) and Virtual Reality (VR), compact Heads Up Displays (HUDs) for aviation and road transport, and sensors for biometric and laser radar (LIDAR) applications. As many of these applications are directed at consumer products, there is a growing requirement for efficient low cost means for manufacturing holographic waveguides in large volumes.

### SUMMARY OF THE DISCLOSURE

Various embodiments are directed to a reactive monomer mixture material including: a co-initiator; a photo-initiator dye; photopolymerizable monomers; and a non-reactive material, where the co-initiator includes an amine synergist, and where the photo-initiator dye includes a high extinction coefficient near recording/excitation wavelengths. It has been discovered that using a co-initiator which is a liquid tertiary amine may enable manufacturing of a large area grating with limited defects. Further, it has been discovered that using a photo-initiator dye including a high extinction coefficient leads to a grating with a high diffraction efficiency and limited defects.

### BRIEF DESCRIPTION OF THE DRAWINGS

The description will be more fully understood with reference to the following figures and data graphs, which are presented as exemplary embodiments of the invention and should not be construed as a complete recitation of the scope of the invention.

FIGS. 1A-1D illustrates various stages of an exemplary HPDLC manufacturing process for manufacturing an HPDLC grating.

FIGS. 2A and 2B are images of an example waveguide including an example large area diffractive grating.

FIG. 3 is an image of an example waveguide including an example large area diffractive grating.

FIG. 4 is an image of an example waveguide including an example large area diffractive grating.

FIG. 5 illustrates an example exposure labeled with beam power measurements across various portions of the coating during exposure.

FIG. 6A conceptually illustrates an example a waveguide display.

FIG. 6B conceptually illustrates typical ray paths in the waveguide display illustrated in FIG. 6A.

### DETAILED DESCRIPTION

There is a growing interest in the use of various gratings on waveguides in order to provide a variety of functions. These gratings include angle multiplexed gratings, color multiplexed gratings, fold gratings, dual interaction gratings, rolled K-vector gratings, crossed fold gratings, tessellated gratings, chirped gratings, gratings with spatially varying refractive index modulation, gratings having spatially varying grating thickness, gratings having spatially varying average refractive index, gratings with spatially varying refractive index modulation tensors, and gratings having spatially varying average refractive index tensors. In some embodiments, gratings may diffract various polarizations of light (e.g. S-polarized light and P-polarized light).

One specific class of gratings includes surface relief gratings (SRGs) which may be used to diffract either P-polarized light or S-polarized light. SRGs are typically fabricated through processes such as nano imprint lithography. SRGs tend to be thin (20-200 nm) because of the difficulty of making nano-imprint lithography (NIL) processes work with deep grating structures. Typical SRGs are generally either P-polarization selective or S-polarization selective, leading to a 50% efficiency loss with unpolarized light sources such as organic light emitting diodes (OLEDs) and light emitting diodes (LEDs). One specific class of SRGs, deep SRGs may be advantageous because they may diffract S-polarization light with high efficiency. Combining S-polarization diffracting and P-polarization diffracting gratings may provide a theoretical 2× improvement over waveguides using P-diffracting gratings only. Holographic polymer dispersed liquid crystal (HPDLC) may be used to manufacture either or both of typical shallow SRGs or deep SRGs. HPDLC gratings such as SBGs are formed by phase separation and comprise alternative LC-rich and polymer-rich regions.

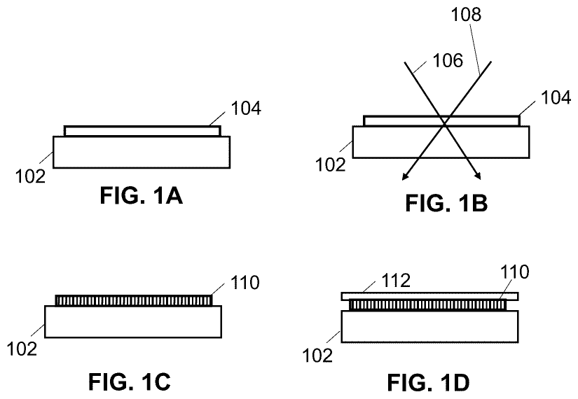

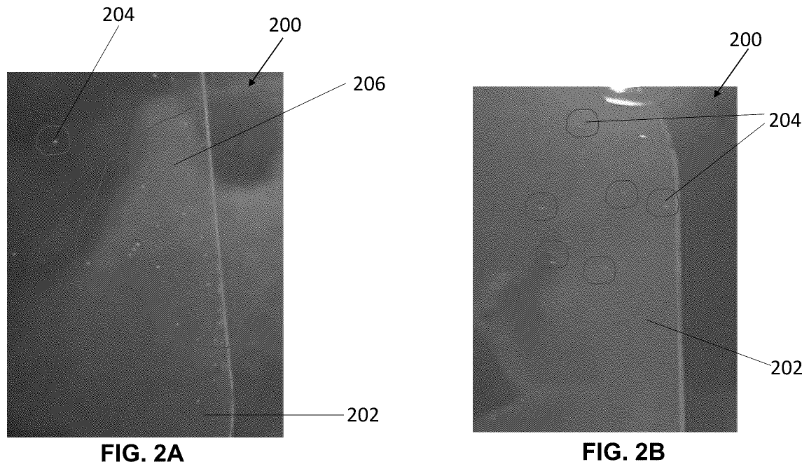

FIGS. 1A-1D illustrates various stages of an exemplary HPDLC manufacturing process for manufacturing an HPDLC grating. At FIG. 1A, a coating 104 is applied to a substrate 102 from a reactive monomer mixture material such as an HPDLC mixture. In some embodiments, the HPDLC mixture may include, among other things, a photosensitive or photopolymerizable monomer, a photo-initiator dye, and a co-initiator. In some embodiments, the photopolymerizable monomers include acrylates or methacrylates. In some embodiments, the mixture may further include a non-reactive material such as liquid crystal which is inactive to the light. In some embodiments the co-initiator may be a liquid monomer or a solid monomer. Advantageous results of co-initiator including a liquid amine synergist (e.g. a tertiary amine) are discussed in connection with FIGS. 2A and 2B. In some embodiments, the HPDLC mixture may include nanoparticles. The nanoparticles may be included in or substitute for the photopolymerizable monomer.

At FIG. 1B, the coating 104 is then exposed with holographic exposure beams 106/108. The holographic exposure beams may be used to phase separate the mixture into alternating polymer rich regions and non-reactive material regions. In some embodiments, the exposure may be performed by a flood exposure technique in which the entire coating 104 is exposed at the same time. A flood exposure technique may be used for a coating 104 which is of small surface area. However, as surface areas get larger power fluctuations within the flood exposure create irregularities within the coating 104 after exposure. These irregularities may include incomplete, uncontrolled, or random polymerizations.

In order to solve this issue, alternative exposure techniques have been contemplated. These alternative exposure techniques include line-scan techniques where the beams are exposed to a portion of the coating 104 and then smoothly scanned across the coating 104 until the entire coating 104 is exposed. In some embodiments, the line-scan technique may be performed on a vertical portion of the coating 104 and then moved to a lower vertical position to expose another vertical portion of the coating 104 until the entire coating 104 is exposed. Further, in some embodiments, the exposure technique may include a stepping process where the holographic exposure beams 106/108 are stepped to portions of the coating 104 until the entire coating 104 is exposed. Good beam uniformity is difficult to achieve in large formats for line-scan exposure processes. Thus, line-scan exposure processes may benefit from HPDLC mixtures with a sensitivity that is better optimized to compensate for beam power variability than a HPDLC mixture designed for flood exposure. An HPDLC mixture with tolerance to variability of beam power would be beneficial. It has been discovered that some formulations of HPDLC mixtures may result in holographic recording issues after exposure (e.g. blow outs). Examples of these issues are described below in connection with FIGS. 2A and 2B.

At FIG. 1C, after the holographic exposure beams 106/108 are applied, a HPDLC grating 110 remains on the surface of substrate 102. The HPDLC grating 110 includes alternative polymer rich regions and non-reactive material regions. In some embodiments, the non-reactive material regions may include liquid crystal material. The HPDLC grating 110 may form a shallow SRG or a deep SRG. In some embodiments, the LC may be extracted from the HPDLC grating 110 to form a surface relief grating such as a shallow SRG or deep SRG. At FIG. 1D, a protective layer 112 may be placed on top of the HPDLC grating 110. In some instances, the protective layer 112 may be a moisture and oxygen barrier with scratch resistance capabilities.

HPDLC manufacturing process starts with an HPDLC mixture. The HPDLC mixture may include, among other things, at least one monomer, a co-initiator, and a photo-initiator dye. During exposure, the photo-initiator dye is used to stimulate the polymerization process. The photo-initiator dye absorbs photons of exposure light which stimulate a quantum state leading to an electron being transferred to the co-initiator. The resulting free radical provides the starting point for growing a polymer chain by successive addition of monomer molecules. In some embodiments, a chain extender can be added to the mixture to cross-link the polymer chains into a complex 3D polymer network.

While it would advantageous for all of the dye to be consumed during the exposure process, not all the dye may be consumed and in the course of exposure, the dye concentration levels off to a non-zero plateau. It is advantageous to have as little dye remaining after exposure since residual dye may lead to absorption of useful light during operation which can contribute to haze.

The co-initiator may be a secondary amine such as:

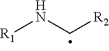

The secondary amine may include an initiation point represented by “·”, a first reactive monomer (R₁), and a second reactive monomer (R₂). R₁ may be an aromatic group such as phenyl. Aromatic groups may be bulky affecting solubility and compatibility with rest of the polymer chain. Thus, the secondary amine includes R₂ as an electron withdrawing functional group such as, but not limited to, carboxylic acids, cyano, or chloro/halogens. The secondary amine includes a hydrogen atom bonded to the nitrogen.

N-phenyl glycine (NPG) is one example of a secondary amine:

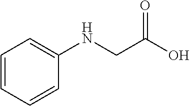 [SMILES: O=C(O)CNc1ccccc1]

NPG includes a phenyl group as R₁ which may make the monomer bulky. R₂ may be a carboxylic acid which increases the reactivity of the molecule. However, the carboxylic acid may release CO₂ during polymerization which may create unwanted defects in the manufactured grating. NPG is typically in a solid state mixed with other components of the HPDLC mixture prior to exposure.

FIGS. 2A and 2B are images of an example waveguide 200 including an example large area diffractive grating 202. This large area diffractive grating 202 was produced using a line-scan exposure technique. As illustrated, the large area diffractive grating 202 includes unwanted defects 204. These defects 204 may create defect areas 206 which may be detrimental to the performance of the large area diffractive grating 202. HPDLC gratings are created by phase separation of the HPDLC mixture during exposure into domains of different refractive indices. These HPDLC mixtures may be multi-component mixtures including liquid monomers, solid (or semi solid) dyes, and liquid crystals. Prior to exposure, these HPDLC mixtures are in a homogenous state. During exposure, the monomers react into polymers and move to neighboring regions creating dark/bright contrast. Any localized disturbance during this phase separation can create ‘blow-out’. These example large area diffractive gratings 202 were manufactured using an HPDLC mixture including a co-initiator including a secondary amine such as NPG.

Without limitation to any particular theory, as discussed above, secondary amines such as NPG include an electron withdrawing functional group such as carboxylic acid. During exposure, the electron withdrawing functional group may release a gas such as carbon dioxide. This gas may create unwanted diffraction of beams during exposure which may cause the blowouts. For example, a line scan process may increase the localized temperature at the recording plate which may release the gas from the recording material. The gas from the recording material may form bubbles which can scatter light triggering blowouts.

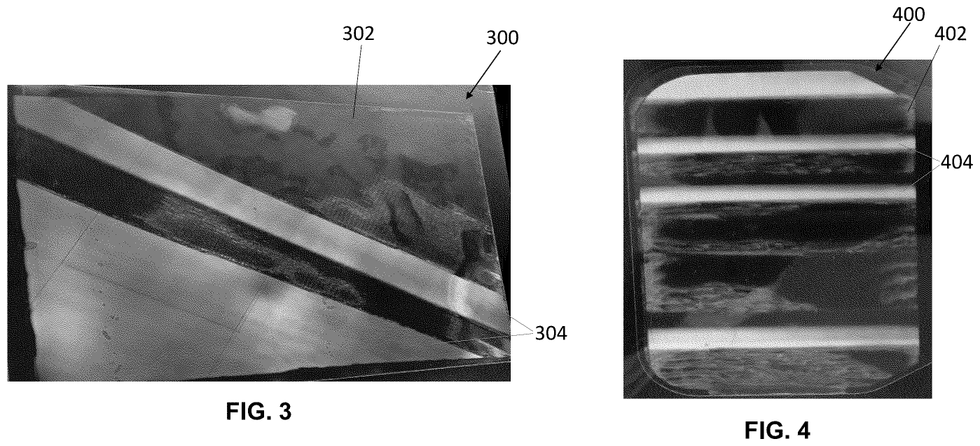

FIG. 3 is an image of an example waveguide 300 including an example large area diffractive grating 302. This large area diffractive grating 302 was produced using a line-scan exposure technique. The HPDLC mixture used includes a co-initiator including a secondary amine such as NPG. As illustrated, the large area diffractive grating 302 includes unwanted defect areas 304. FIG. 4 is an image of an example waveguide 400 including an example large area diffractive grating 402. This large area diffractive grating 402 was produced using a line-scan exposure technique. As illustrated, the large area diffractive grating 402 includes unwanted defect areas 404. The HPDLC mixture used includes a co-initiator including a secondary amine such as NPG.

It has been discovered that using an HPDLC mixture including a co-initiator including a liquid tertiary amine instead of a solid secondary amine decreases the amount of defects present after line-scan exposure. A representative structure of a tertiary amine is shown here:

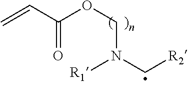

The tertiary amine may include an initiation point represented by ‘·’, a first reactive monomer (R₁′) and a second reactive monomer (R₂′). Unlike the secondary amine, the tertiary amine does not include a hydrogen bonded to the central nitrogen. R₁′ or R₂′ may be an aliphatic group. The tertiary amine may not include an aromatic group as in the secondary amine. Without limitation to any particular theory, secondary amines have a more variable response due to variability in exposure beam power than the tertiary amine.

Further, NPG is difficult to dissolve. Incomplete dissolution may produce more defects after the line-scan exposure. In comparison, a tertiary amine is a liquid or can be dissolved by adding to the resin mixtures and thus may produce less defects after the line-scan or similar holographic beam exposure.

In some embodiments, R₁′ and/or R₂′ are oligomethylene chains, phenyls, substituted phenyls, pendant chains, or linking groups. In some embodiments, the tertiary amine includes acrylates or methacrylates.

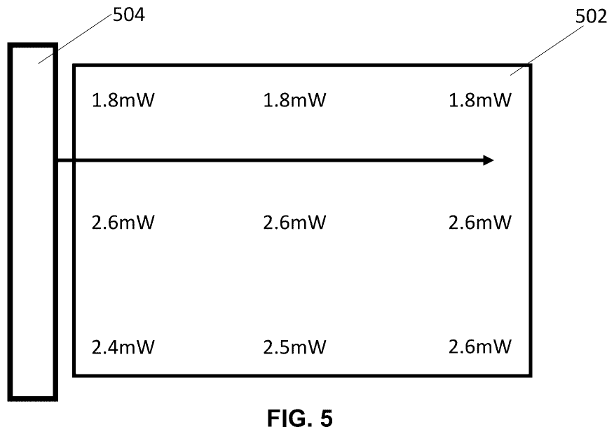

FIG. 5 illustrates an example exposure labeled with beam power measurements across various portions of the coating during exposure. A HPDLC mixture coated substrate 502 is exposed to a line-beam light source 504. The line-beam light source 504 is scanned across the coated substrate 502. As discussed above, the line-beam light source 504 may provide an uneven distribution of light beam powers to various portions of the coated substrate 502. For example, the top of the coated substrate 502 may be exposed to a consistent beam of 1.8 mW whereas the center of the coated substrate 502 may be exposed to a higher consistent beam of 2.6 mW. Further, as illustrated at the bottom portion of the coated substrate 502, the beam may vary across various positions of the coated substrate 502. The wattage may increase while scanned across the coated substrate 502. As illustrated, the bottom portion of the coated substrate 502 may be exposed to a beam which increases in power from 2.4 mW to 2.6 mW while scanning across the coated substrate 502. Beneficially, a HPDLC mixture which is less sensitive to fluctuations in power (e.g. reacts similarly to a beam of 1.8 mW as a beam of 2.6 mW) would be advantageous. As discussed above, tertiary amines are less sensitive to variations in beam power than secondary amines and thus more suited for line-scan processes. In some embodiments, an expanded line scan beam may be used instead of an intense pencil beam. The expanded line scan beam may slow down diffusion and/or phase separation which may decrease the number of defects in the exposed grating. In some embodiments, the holographic exposure beams include a beam power difference of 1 mW or less while scanned across the holographic polymer dispersed liquid crystal mixture.

### Example Photo-Initiator Dye Types

Various example photo-initiator dyes with different properties are illustrated in Table 1:

| Extinction coefficient | |
|---|---|
| (M−1cm−1, ε₁) | DE, % |
| >80,000 | 80+, uniform |
| >70,000 | 75+ |
| >60,000 | 70+ |
| <50,000 | 60+, non-uniform |

Table 1 illustrates various HPDLC gratings manufactured using various HPDLC mixtures including photo-initiator dyes with different extinction coefficients (81) at a fixed first recording wavelength (λ₁). As illustrated, a higher extinction coefficient generally yields a higher diffraction efficiency for the HPDLC gratings. Thus, it would be advantageous to use a dye with the highest possible extension coefficient.

In some embodiments, the photo-initiator dye may include an extinction coefficient of greater than 60,000 M⁻¹ cm⁻¹ at λ₁. In some embodiments, the photo-initiator dye may include an extinction coefficient greater than 70,000 M⁻¹ cm⁻¹ at λ₁.

Various example photo-initiator dye consistencies are illustrated in Table 2:

| Absorption ratio, ε₁/ε₂ | DE, % |
|---|---|
| >15 | 80+, uniform |
| >11 | 75+ |
| >8 | 70+ |
| <5 | 60+, non-uniform |

Table 2 illustrates an absorption ratio which equals ε₁ divided by ε₂ where ε₂ is extinction coefficient at a second recording wavelength (λ₂). Where, λ₁ is close to Δₘₐₓ (peak absorption wavelength) greater than 2. Advantageously, higher the absorption ratio yields higher diffraction efficiency. In some embodiments, the absorption ratio may be greater than 8. In some embodiments, the absorption ratio may be greater than 11. In some embodiments, the first recording wavelength includes a peak recording wavelength of the photo-initiator dye and the second recording wavelength is a wavelength within an ultraviolet or visible spectrum.

In some embodiments, the photo-initiator dye may be produced based on a substitution process as described based on the below example chemical formula:

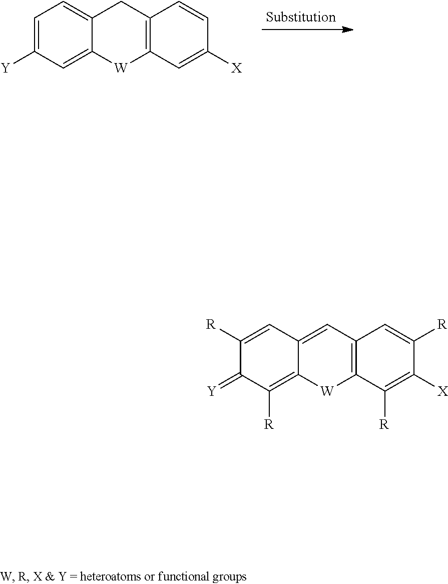

As illustrated, the substitution process yields a compound with multiple heteroatoms (R; can be halogens such as bromine, iodine). However, in some cases, the reaction may end up incomplete with two or three hetero atom group terminations. The higher concentration of tetra substituted compounds, the higher the extinction coefficient may be. Halogens like iodine is known as a heavy atom for assisting triplet excited state formation. An example is photodynamic therapy (PDT). Tetra-substitution in the dye may be helping for triplet excited states by assisting the inter-system crossing. Triplets can improve photoconversion or polymerization. The photo-initiator dye may be a tetra-substituted compound. In some embodiments, the photoinitiator dye may be a tetra-iodo compound. It has been discovered that, a photo-initiator dye including an impurity level of 12.28% may provide a lower extinction coefficient than a photo-initiator dye including an impurity level of 6.54%. In some embodiments, the photo-initiator dye may include less than 10% impurities which may provide a high extinction coefficient. In some embodiments, the photo-initiator dye may have impurity levels of less than 9%, 8%, or 7%.

A first type of photoinitiator dye may include aromatic coumarin, pyrromethanes, or cyanines chromophore types. For example, the first type of photoinitiator dye may be coumarin type. The photoinitiator dye may be in a solvent like toluene. The photo-initiator dye may have an absorption maximum wavelength of about 450 nm, λₘₐₓ˜450 nm, which may be the peak absorption of the dye from its chromophore. The photo-initiator dye may include weak absorption at a recording wavelength. For example, the n-π* electronic transition may not be very strong at the recording wavelength.

A second type of photoinitiator dye may include a hetero-aromatic compound. The second type of photoinitiator dye may be a chromophoric compound. The second type of photoinitiator dye may include fluorones. In some embodiments, the second type of photoinitator dye may include a hetero-aromatic chromophore based on fluorones. For example, the second type of photoinitator dye may be fluorones or similar chromophores with heteroatoms. The photoinitiator dye may be in a solvent such as dimethyl sulphoxide (DMSO). The photo-initiator dye may have a maximum wavelength of about 535 nm, λₘₐₓ˜535 nm. This type of photo-initiator dye may have a very high extinction coefficient at or around recording/excitation wavelengths. There may be a good match between recording wavelength and excitation. The reactive monomer mixture including the second type of photoinitiator dye may be photopolymerized using a free radial polymerization by Norrish Type II photopolymerization. Initiation of free-radical polymerization by a Norrish Type II mechanism involves excitation of the sensitizer dye which may be followed by radical formation from the co-initiator. When the dye absorption matches the recording wavelength, photosensitization may be more effective. Norrish Type II photopolymerization can provide effective phase separation and high optical performance when sensitizing dye absorption is very high at recording wavelengths. Without limitation to any particular theory, radical termination, incomplete polymerization, or ineffective phase separation may occur when excitation wavelength is not well matched with absorption. Polymerization via photosensitization may involve excited states especially triplet excited state. Heavy atoms in the chromophore can increase the rate of inter-system crossing (ISC), thereby the formation rates of triplets. Rate of polymerization may be enhanced due to this process, facilitating better phase separation. It has been demonstrated that gratings manufactured using photosensitive materials including the second type of photoinitiator dye may include a higher diffraction efficiency than gratings manufactured using photosensitive materials including the first type of photoinitiator dye. For example, with a 2 μm thick grating, the gratings manufactured using photosensitive materials including the second type of photoinitiator dye may include a diffraction efficiency of 75% or greater. Whereas, with a 2 μm thick grating, the gratings manufactured using photosensitive materials including the first type of photoinitiator dye may include a diffraction efficiency of less than 65%. Further, it has been demonstrated that gratings manufactured using photosensitive materials including the second type of photoinitiator dye may include a lower haze than gratings manufactured using photosensitive materials including the first type of photoinitiator dye. For example, the gratings manufactured using photosensitive materials including the second type of photoinitiator dye may include a haze of about 0.3%. Whereas, the gratings manufactured using photosensitive materials including the first type of photoinitiator dye may include a haze of greater than 0.5%.

In some embodiments, the choice of type of photoinitiator dye in the photosensitive materials may affect the number of defects present in the manufactured grating. Defects may be dependent on exposure beam power. In some embodiments, the material sensitivity to exposure beam power may be less at lower temperature. When using a photosensitive material including the second type of photoinitiator dye, defects may occur with a fluorone chemistry. However, the second type of photoinitiator dye generally allow for a larger process window than the first type of photoinitiator dye. The defects may still occur at very high flux levels which may be introduced at higher beam powers. The defects may present themselves with increased haze in the manufactured gratings. In some embodiments, defects may also be triggered or assisted by other seeding features in the photosensitive material such as dust, spacer beads, and stray recording light.

In some embodiments, the photoinitiator dye-based photopolymer may be a thiolene based material. The thiolene may include mercapto-ester or thio-acrylates. Gratings manufactured using photosensitive materials including the photoinitiator dye with a thiolene based material may react slowly and require exposure at higher temperatures which may be disadvantageous.

In some embodiments, the addition of nanoparticles to the photosensitive holographic material may decrease the number of defects in the manufactured gratings. Without limitation to any particular theory, there may be clustering of molecules in the holographic photosensitive material during exposure which can lead to clustering of molecules forming LC ‘droplets’. Nematic droplets may be considered a seeding cluster which may be decreased through the addition of nanoparticles. The nanoparticles may include non-reactive nanoparticles or reactive nanoparticles. The nanoparticles may include capped inorganic materials with a core shell. The core shell may include silica, zirconium, and/or titanium.

Example waveguide-based display

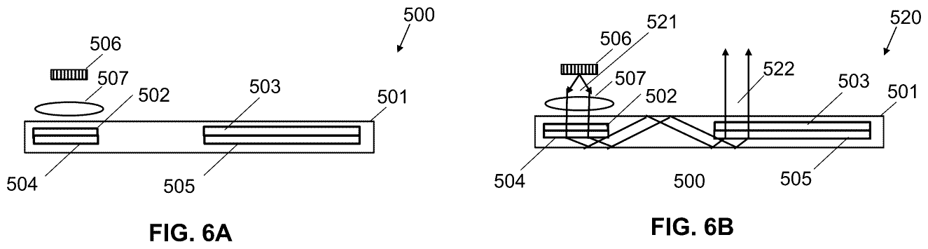

The gratings described above may be implemented in a waveguide display. FIG. 6A conceptually illustrates an example a waveguide display. As shown, the apparatus 500 includes a waveguide 501 supporting input 502 and output 503 gratings. The input 502 and output 503 gratings may have high diffraction efficiency for P-polarized light in a first wavelength band and input 504 and output 505 gratings may have high diffraction efficiency for S-polarized light in the first wavelength band. Input grating 502 and output gratings 503 may be conventional SRG gratings whereas input grating 504 and output grating 505 may be deep SRG gratings such as HPDLC gratings. In the illustrative embodiment, the S and P diffracting gratings 502-505 can be layered with no air gap required. In other embodiments, the grating layers can be separated by an air gap or a transparent layer.

The apparatus 500 further includes an image source 506 emitting light with an emission spectral bandwidth that includes the first wavelength band and a collimation lens 507 for projecting light from the image source OLED microdisplay 506 into a field of view. The image source 506 may be an emissive microdisplay such as OLED microdisplay or a non-emissive microdisplay such as LCoS and MEMS based displays. Non-emissive microdisplays may include light sources. Emissive displays may emit unpolarized light which includes both S and P polarized light. It would be advantageous to include diffraction gratings which can diffract both S and P polarized light with high efficiency.

FIG. 6B conceptually illustrates typical ray paths in the waveguide display 500 illustrated in FIG. 6A. In the embodiment 520 illustrated in FIG. 6B, an image source 506 is configured to emit light 521 in a first wavelength band, which is collimated and projected into a field of view by a collimator lens 507. In some embodiments, the emitted light 521 may be polarized or unpolarized light. With unpolarized light, the S-polarized emission from the image source 506 can be coupled into a total internal reflection path in a waveguide 501 by an S-diffracting input grating 504 and extracted from the waveguide 501 by an S-diffracting output grating 505. Still referring to the case of unpolarized light, P-polarized light from the image source 506 can be in-coupled and extracted using P-diffracting input grating 502 and output grating 503 in a similar fashion. Dispersion can be corrected for both S and P light provided that the input and output gratings spatial frequencies are matched. The output gratings 503,505 are configured to output light 522 with both S and P polarization. The input grating 502 and output grating 503 may be conversional SRGs. The input grating 504 and output grating 505 may be the deep SRGs described above. Advantageously, a waveguide display including input and output gratings that diffract both S and P polarized light with a high degree of efficiency may more efficiently utilize light.

### EXAMPLE EMBODIMENTS

Although many embodiments of the invention have been described in detail, it should be appreciated that the invention may be implemented in many other forms without departing from the spirit or scope of the invention. For example, embodiments such as enumerated below are contemplated:

Item 1: A reactive monomer mixture material comprising:
a co-initiator;
a photo-initiator dye;
photopolymerizable monomers; and
a non-reactive material,
wherein the co-initiator comprises an amine synergist, and
wherein the photo-initiator dye comprises a high extinction coefficient near recording/excitation wavelengths.

Item 2: The material of item 1, wherein the amine synergist includes a tertiary amine group:

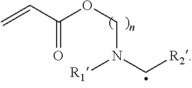

Item 3: The material of item 2, wherein R₁′ and/or R₂′ comprise an aliphatic compound or an aromatic compound.

Item 4: The material of item 3, wherein R₁′ and/or R₂′ are oligomethylene chains, phenyls, substituted phenyls, pendant chains, or linking groups.

Item 5: The material of item 4, wherein the linking groups are functionalized.

Item 6: The material of item 2, wherein R₁′ and/or R₂′ are not electron withdrawing functional groups.

Item 7: The material of item 1, wherein the amine synergist comprises a liquid monomer solution.

Item 8: The material of item 7, wherein the amine synergist further comprises acrylates or methacrylates.

Item 9: The material of item 1, wherein the amine synergist comprises a tertiary amine.

Item 10: The material of item 1, wherein the photopolymerizable monomers comprise acrylates or methacrylates.

Item 11: The material of item 10, wherein the photopolymerizable monomers further comprise nanoparticles.

Item 12: The material of item 11, wherein the photopolymerizable monomers further comprises thiolene.

Item 13: The material of item 12, wherein the thiolene comprise mercapto-ester or thio-acrylates.

Item 14: The material of item 1, wherein the extinction coefficient of the photo-initiator dye is greater than 60,000 M 1 cm 1 at a first recording wavelength.

Item 15: The material of item 14, wherein the extinction coefficient of the photo-initiator dye is greater than 70,000 M⁻¹ cm⁻¹ at the first recording wavelength.

Item 16: The material of item 1, wherein an absorption ratio of the photo-initiator dye is greater than 8.

Item 17: The material of item 16, wherein the absorption ratio of the photo-initiator dye is greater than 11.

Item 18: The material of item 16, the absorption ratio comprises the extinction coefficient of the photo-initiator dye at a first recording wavelength divided by the extinction coefficient of the photo-initiator dye at a second recording wavelength, wherein the first recording wavelength is larger than the second recording wavelength.

Item 19: The material of item 18, wherein the first recording wavelength comprises a peak recording wavelength of the photo-initiator dye and the second recording wavelength is a wavelength within an ultraviolet or visible spectrum.

Item 20: The material of item 1, wherein the photo-initiator dye comprises a chromophoric compound.

Item 21: The material of item 20, wherein the photo-initiator dye further comprises fluorones.

Item 22: The material of item 1, wherein the non-reactive material comprises liquid crystal material and/or nanoparticles.

Item 23: The material of item 1, wherein the photo-initiator dye comprises a tetra-iodo compound.

Item 24: The material of item 23, wherein the tetra-iodo compound contains less than 10% impurities.

Item 25: A method of creating a grating, the method comprising:
providing a substrate;
coating the substrate with a holographic polymer dispersed liquid crystal mixture comprising:
   a co-initiator;
   a photo-initiator dye;
   photopolymerizable monomers; and
   a non-reactive material,
   wherein the co-initiator comprises an amine synergist, and
   wherein the photo-initiator dye comprises a high extinction coefficient near recording/excitation wavelengths; and
exposing the holographic polymer dispersed liquid crystal mixture to holographic exposure beams in a line scan fashion.

Item 26: The method of item 25, wherein the holographic exposure beams comprise a beam power difference of 1 mW or less while scanned across the holographic polymer dispersed liquid crystal mixture.

Item 27: The method of item 25, wherein the amine synergist includes a tertiary amine group:

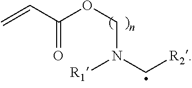

Item 28: The method of item 27, wherein R₁′ and/or R₂′ comprise an aliphatic compound or an aromatic compound.

Item 29: The method of item 28, wherein R₁′ and/or R₂′ are oligomethylene chains, phenyls, substituted phenyls, pendant chains, or linking groups.

Item 30: The method of item 29, wherein the linking groups are functionalized.

Item 31: The method of item 27, wherein R₁′ and/or R₂′ are not electron withdrawing functional groups.

Item 32: The method of item 25, wherein the amine synergist comprises a liquid monomer solution.

Item 33: The method of item 32, wherein the amine synergist further comprises acrylates or methacrylates.

Item 34: The method of item 25, wherein the amine synergist comprises a tertiary amine.

Item 35: The method of item 25, wherein the photopolymerizable monomers comprise acrylates or methacrylates.

Item 36: The method of item 35, wherein the photopolymerizable monomers further comprise nanoparticles.

Item 37: The method of item 36, wherein the photopolymerizable monomers further comprises thiolene.

Item 38: The method of item 37, wherein the thiolene comprise mercapto-ester or thio-acrylates.

Item 39: The method of item 25, wherein the extinction coefficient of the photo-initiator dye is greater than 60,000 M 1 cm 1 at a first recording wavelength.

Item 40: The method of item 39, wherein the extinction coefficient of the photo-initiator dye is greater than 70,000 M⁻¹ cm⁻¹ at the first recording wavelength.

Item 41: The method of item 25, wherein an absorption ratio of the photo-initiator dye is greater than 8.

Item 42: The method of item 41, wherein the absorption ratio of the photo-initiator dye is greater than 11.

Item 43: The method of item 41, the absorption ratio comprises the extinction coefficient of the photo-initiator dye at a first recording wavelength divided by the extinction coefficient of the photo-initiator dye at a second recording wavelength, wherein the first recording wavelength is larger than the second recording wavelength.

Item 44: The method of item 43, wherein the first recording wavelength comprises a peak recording wavelength of the photo-initiator dye and the second recording wavelength is a wavelength within an ultraviolet or visible spectrum.

Item 45: The method of item 25, wherein the photo-initiator dye comprises a chromophoric compound.

Item 46: The method of item 45, wherein the photo-initiator dye further comprises fluorones.

Item 47: The method of item 25, wherein the non-reactive material comprises liquid crystal material and/or nanoparticles.

Item 48: The method of item 25, wherein the photo-initiator dye comprises a tetra-iodo compound.

Item 49: The method of item 48, wherein the tetra-iodo compound contains less than 10% impurities.

Item 50: A reactive monomer mixture material comprising:
a co-initiator;
a photo-initiator dye; and
nanoparticles,
wherein the co-initiator comprises an amine synergist, and
wherein the photo-initiator dye comprises a high extinction coefficient near recording/excitation wavelengths.

Item 51: The material of item 50, wherein the amine synergist includes a tertiary amine group:

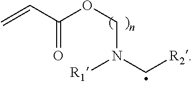

Item 52: The material of item 51, wherein R₁′ and/or R₂′ comprise an aliphatic compound or an aromatic compound.

Item 53: The material of item 52, wherein R₁′ and/or R₂′ are oligomethylene chains, phenyls, substituted phenyls, pendant chains, or linking groups.

Item 54: The material of item 53, wherein the linking groups are functionalized.

Item 55: The material of item 51, wherein R₁′ and/or R₂′ are not electron withdrawing functional groups.

Item 56: The material of item 50, wherein the amine synergist comprises a liquid monomer solution.

Item 57: The material of item 56, wherein the amine synergist further comprises acrylates or methacrylates.

Item 58: The material of item 50, wherein the amine synergist comprises a tertiary amine.

Item 59: The material of item 50, wherein the extinction coefficient of the photo-initiator dye is greater than 60,000 M⁻¹ cm⁻¹ at a first recording wavelength.

Item 60: The material of item 59, wherein the extinction coefficient of the photo-initiator dye is greater than 70,000 M⁻¹ cm⁻¹ at the first recording wavelength.

Item 61: The material of item 50, wherein an absorption ratio of the photo-initiator dye is greater than 8.

Item 62: The material of item 61, wherein the absorption ratio of the photo-initiator dye is greater than 11.

Item 63: The material of item 61, the absorption ratio comprises the extinction coefficient of the photo-initiator dye at a first recording wavelength divided by the extinction coefficient of the photo-initiator dye at a second recording wavelength, wherein the first recording wavelength is larger than the second recording wavelength.

Item 64: The material of item 63, wherein the first recording wavelength comprises a peak recording wavelength of the photo-initiator dye and the second recording wavelength is a wavelength within an ultraviolet or visible spectrum.

Item 65: The material of item 50, wherein the photo-initiator dye comprises a chromophoric compound.

Item 66: The material of item 65, wherein the photo-initiator dye further comprises fluorones.

Item 67: The material of item 50, wherein the photo-initiator dye comprises a tetra-iodo compound.

Item 68: The material of item 67, wherein the tetra-iodo compound contains less than 10% impurities.

Item 69: The material of item 50, wherein the nanoparticles comprise non-reactive nanoparticles or reactive nanoparticles.

Item 70: The material of item 69, wherein the nanoparticles comprise capped inorganic materials with a core shell.

Item 71: The material of item 70, wherein the core shell comprises silica, zirconium, and/or titanium.

### Doctrine of Equivalents

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A reactive monomer mixture material comprising:
a co-initiator;
a photo-initiator dye;
photopolymerizable monomers; and
a non-reactive material,
wherein the co-initiator comprises an amine synergist, and
wherein the photo-initiator dye comprises a high extinction coefficient near recording/excitation wavelengths.

2. The material of claim 1, wherein the amine synergist includes a tertiary amine group:

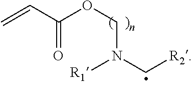

3. The material of claim 2, wherein R₁′ and/or R₂′ comprise an aliphatic compound or an aromatic compound.

4. The material of claim 3, wherein R₁′ and/or R₂′ are oligomethylene chains, phenyls, substituted phenyls, pendant chains, or linking groups.

5. The material of claim 4, wherein the linking groups are functionalized.

6. The material of claim 2, wherein R₁′ and/or R₂′ are not electron withdrawing functional groups.

7. The material of claim 1, wherein the amine synergist comprises a liquid monomer solution.

8. The material of claim 7, wherein the amine synergist further comprises acrylates or methacrylates.

9. The material of claim 1, wherein the amine synergist comprises a tertiary amine.

10. The material of claim 1, wherein the photopolymerizable monomers comprise acrylates or methacrylates.

11. The material of claim 10, wherein the photopolymerizable monomers further comprise nanoparticles.

12. The material of claim 11, wherein the photopolymerizable monomers further comprises thiolene.

13. The material of claim 12, wherein the thiolene comprise mercapto-ester or thio-acrylates.

14. The material of claim 1, wherein the extinction coefficient of the photo-initiator dye is greater than 60,000 M⁻¹ cm⁻¹ at a first recording wavelength.

15. The material of claim 14, wherein the extinction coefficient of the photo-initiator dye is greater than 70,000 M⁻¹ cm⁻¹ at the first recording wavelength.

16. The material of claim 1, wherein an absorption ratio of the photo-initiator dye is greater than 8.

17. The material of claim 16, wherein the absorption ratio of the photo-initiator dye is greater than 11.

18. The material of claim 16, the absorption ratio comprises the extinction coefficient of the photo-initiator dye at a first recording wavelength divided by the extinction coefficient of the photo-initiator dye at a second recording wavelength, wherein the first recording wavelength is larger than the second recording wavelength.

19. The material of claim 18, wherein the first recording wavelength comprises a peak recording wavelength of the photo-initiator dye and the second recording wavelength is a wavelength within an ultraviolet or visible spectrum.

20. The material of claim 1, wherein the photo-initiator dye comprises a chromophoric compound.

21. The material of claim 20, wherein the photo-initiator dye further comprises fluorones.

22. The material of claim 1, wherein the non-reactive material comprises liquid crystal material and/or nanoparticles.

23. The material of claim 1, wherein the photo-initiator dye comprises a tetra-iodo compound.

24. The material of claim 23, wherein the tetra-iodo compound contains less than 10% impurities.
